(19) United States
(12) Patent Application Publication
(10) Pub. No.: US 2012/0275154 A1
(43) Pub. Date: Nov. 1, 2012

(54) Dual sided linear light emitting device

(75) Inventors: William Hood, Northbrook, IL (US); Liangfu Zhou, Lincolnshire, IL (US)

(73) Assignee: LED LIGHTING INC., Northbrook, IL (US)

(21) Appl. No.: 13/458,709

(22) Filed: Apr. 27, 2012

Related U.S. Application Data
(60) Provisional application No. 61/479,801, filed on Apr. 27, 2011.

(51) Int. Cl. F21V 21/005; F21V 29/00; H05K 13/00; F21V 31/00

(52) U.S. Cl. 362/249.02; 29/592.1

(57) ABSTRACT

In one embodiment, a light emitting device comprises two linear arrays of light emitting diodes positioned on opposite sides of a linear heat conducting member. In one embodiment, a light emitting device comprises a heat conducting member linear in a first linear direction with a first surface and a second surface opposite the first surface; a first linear array of light emitting diodes thermally coupled to the first surface; a second linear array of light emitting diodes thermally coupled to the second surface; a first light transmitting cover positioned to receive and transmit light from the first linear array of light emitting diodes; and a second light transmitting cover positioned to receive and transmit light from the second linear array of light emitting diodes. In another embodiment, a method of manufacturing a light emitting device comprises snapping or sliding extensions of the light transmitting covers into the grooves.

### CROSS REFERENCE TO RELATED APPLICATION

This application claims the benefit of U.S. Provisional Application No. 61/479,801, entitled “Linear light emitting device with a cover comprising an extension and a heat sink comprising a groove,” filed Apr. 27, 2011, the entire contents of which is incorporated herein by reference.

### BACKGROUND

The subject matter disclosed herein generally relates to light emitting devices such as light fixtures, light bulbs, replacement light bulbs, devices comprising light emitting diodes, and their components and method of manufacture. Light emitting devices are needed which are thinner, lighter weight, replaceable, cheaper to manufacture, scalable to large sizes, and have replaceable components.

### BRIEF DESCRIPTION OF THE DRAWINGS

FIG. 1 is a perspective view of an embodiment of a secure and removable connector means for connecting a first plurality of leads to a second plurality of leads utilizing a cable tie.

FIG. 2 is perspective view of an embodiment of a light emitting device in the form of a LED tube that can be disposed in a linear fluorescent light fixture comprising a single row of LEDs.

FIG. 3 is a cross-sectional view of the light emitting device of FIG. 2 with the light transmitting cover separate from the aluminum heat sink extrusion.

FIG. 4 is a cross sectional view of the light emitting device of FIG. 2 with the light transmitting cover attached to the aluminum heat sink extrusion.

FIG. 5 is a cross sectional view of a dual sided light emitting device before assembly of the two light transmitting covers.

FIG. 6 is a cross sectional side view of the dual sided light emitting device of FIG. 5 with the light transmitting covers positioned in the grooves.

FIG. 7 is a perspective view of the dual sided light emitting device of FIG. 6.

FIG. 8 is a polar plot of the luminous intensity distribution profile in the x-y plane of the light from the dual sided light emitting device of FIG. 7.

### DETAILED DESCRIPTION

The features and other details of several embodiments will now be more particularly described. It will be understood that particular embodiments described herein are shown by way of illustration and not as limitations. The principal features can be employed in various embodiments without departing from the scope of any particular embodiment.

### Light Emitting Device

In one embodiment, a light emitting device comprises at least one linear array of light sources disposed on a heat conducting member such as a hollow aluminum extrusion. In one embodiment, the light emitting device comprises a single linear array of light sources disposed at a pitch such that the light is perceived as a single line of light by an individual with a visual acuity of 1 arcminute at a distance of 1 meter. In another embodiment, the light emitting device comprises a single linear array of light sources on one side of a heat conducting member and a single linear array of light sources on the opposite side of the heat conducting member. In another embodiment, the light sources are a linear array of Light Emitting Diodes (LEDs) disposed on a circuit board thermally coupled to an aluminum extrusion heat sink. In another embodiment, the light emitting device comprises an electrical connector means that is secured and can be readily unconnected utilizing a cable tie. In one embodiment, the light emitting device is a light emitting tube with a substantially circular cross-section with connector pins on opposite sides that can be electrically and mechanically coupled to a linear fluorescent light fixture as a replacement bulb.

### Light Source

In one embodiment, a light emitting device comprises an array of two or more light sources. In another embodiment, a substantially linear light emitting device comprises a linear array of LEDs disposed upon a circuit board with a linear direction substantially parallel to the length direction of the linear light emitting device. In one embodiment, the light emitting device comprises a plurality of light sources arranged in an array, on opposite sides of a housing or heat conducting member, the same side of a housing or heat conducting member, or on multiple sides or faces of a housing or heat conducting member. In one embodiment, the array of light sources is a linear array with discrete LED packages comprising at least one LED die. In another embodiment, a light emitting device comprises a plurality of light sources within one package disposed to emit light toward a surface for illumination. In one embodiment, the light emitting device comprises at least one selected from the group of: 2, 3, 4, 5, 6, 8, 9, 10, 20, 40, 60, 80, 100, 120, 140, 160, 180, 200, 220, 240, 260, 280, 300, 320, 340, 360, 380, and 400 light emitting diodes. In another embodiment, the light emitting diodes are thermally coupled to a heat conducting circuit board, such as for example without limitation, an aluminum or metal core circuit board.

### Spectral Properties of the Light Source

In one embodiment, a light emitting device comprises at least one broadband light source that emits light in a wavelength spectrum larger than 100 nanometers. In another embodiment, a light emitting device comprises at least one narrowband light source that emits light in a narrow bandwidth less than 100 nanometers. In another embodiment, a light emitting device comprises at least one broadband light source that emits light in a wavelength spectrum larger than 100 nanometers or at least one narrowband light source that emits light in a narrow bandwidth less than 100 nanometers. In one embodiment a light emitting device comprises at least one narrowband light source with a peak wavelength within a range selected from the group of 300 nm-350 nm, 350 nm-400 nm, 400 nm-450 nm, 450 nm-500 nm, 500 nm-550 nm, 550 nm-600 nm, 600 nm-650 nm, 650 nm-700 nm, 700 nm-750 nm, 750 nm-800 nm, and 800 nm-1200 nm. The light sources may be chosen to match the spectral qualities of red, green and blue such that collectively when used in a light emitting device, a range of colors may be achieve by adjusting the relative light output of one or more LEDs. In one embodiment, at least one light source is a white LED comprising a red, green, and blue LED. In another embodiment, the LED is a blue or ultraviolet LED combined with a phosphor. In another embodiment, a light emitting device comprises a light source with a first activating energy and a wavelength conversion material which converts a first portion of the first activating energy into a second wavelength different than the first. In another embodiment, the light emitting device comprises at least one wavelength conversion material selected from the group of a fluorophore, phosphor, a fluorescent dye, an inorganic phosphor, photonic bandgap material, a quantum dot material, and a semiconductor wavelength converting material. In another embodiment, the light emitting device comprises white LED light sources. In another embodiment, the light sources comprise LEDs that are at least one selected from the group of: warm white, cool white, neutral white, daylight white, have a correlated color temperature between 2200 K and 2900 K, have a correlated color temperature between 2900 K and 3600 K, have a correlated color temperature between 3600 K and 4500 K, have a correlated color temperature between 4500 K and 4900 K, and have a correlated color temperature between 4900 K and 6600 K.

### Linear Array of Leds

In one embodiment, a linear light emitting device comprises a linear array of LEDs with a pitch, P, disposed parallel to the linear dimension of the light emitting device. In one embodiment, the pitch, P, is less than one selected from the group of 10 mm, 8 mm, 6 mm, 5 mm, 4 mm, 3 mm, and 2 mm. In another embodiment, the dimension d1 of the LED in the linear direction is less than one selected from the group of 10 mm, 8 mm, 6 mm, 5 mm, 4 mm, 3 mm, and 2 mm.

In a further embodiment, the length L2, of the light emitting device is greater than one selected from the group of 100 mm, 150 mm, 300 mm, 400 mm, 500 mm, 600 mm, 700 mm, 900 mm, 1 meter, 1.2 meters, 1.4 meters, 1.6 meters, 1.8 meters, 2 meters, 2.2 meters, and 2.4 meters. In another embodiment, the length, L2, of the light emitting device is one selected from the group of: between 560 and 600 millimeters, between 1170 and 1200 millimeters, and between 2340 and 2400 millimeters.

In a further embodiment, the length L1, of the light emitting region of the light emitting device is greater than one selected from the group of 100 mm, 150 mm, 300 mm, 400 mm, 500 mm, 600 mm, 700 mm, 900 mm, 1 meter, 1.2 meters, 1.4 meters, 1.6 meters, 1.8 meters, 2 meters, 2.2 meters, and 2.4 meters. In another embodiment, the length of the light emitting region, L1, of the light emitting device is one selected from the group of: between 560 and 600 millimeters, between 1170 and 1200 millimeters, and between 2340 and 2400 millimeters.

In one embodiment, the light emitting device comprises a substantially linear array of LEDs with an average density greater than one selected from the group of: 2, 3, 4, 5, 6, 7, 8, 9, and 10 LEDs per linear inch.

### Single Linear Array of Leds on One Side

In one embodiment, a linear light emitting device comprises a single linear array of LEDs disposed substantially parallel to the linear dimension of the light emitting device on a first side of a heat conducting member. In one embodiment, the light emitting device is oriented such that the single, substantially linear array of LEDs emits light out of a light fixture when positioned within the light fixture.

### Two Linear Arrays on Opposite Sides of a Heat Conducting Member

In one embodiment, a linear light emitting device comprises a substantially linear array of LEDs disposed parallel to the linear dimension of the light emitting device and thermally coupled to a first surface of a heat conducting member and a second substantially linear array of LEDs disposed parallel to the linear dimension of the light emitting device and thermally coupled to a second surface of the heat conducting member opposite the first surface. In one embodiment, the light sources of the light emitting device providing illumination are contained within a first substantially linear array on the first surface of a heat conducting member and a second substantially linear array on a second surface of the heat conducting member opposite the first surface.

### Spatial Uniformity of Line of Light

In one embodiment, the light emitting device has a spatial luminance profile with a linear bright region on at least one side with a substantially uniform linear luminance along the line of the linear array of LEDs. In one embodiment, the luminance uniformity, U, measured at the surface of the light transmitting cover along a line parallel to the LEDs is greater than one selected from the group of 60%, 70%, 80%, 85%, 90%, and 95% with the uniformity, U, defined by the equation:

$$U = \frac{{L}_{min}}{{L}_{max}}$$

where Lₘᵢₙ is the average minimum luminance along the line and Lₘₐₓ is the average maximum luminance long the line when measured with a 5 mm or greater spot size. In one embodiment, the light transmitting cover is substantially clear and has a haze less than 10%. In another embodiment, the light transmitting cover is diffuse and has a haze (when flattened to a non-arcuate shape by thermoforming and/or pressure and measured according to ASTM D1003) greater than one selected from the group of 10%, 20%, 30%, 40%, 50%, 60%, 70%, 80%, and 90%. In the haze measurements, when the sample is arcuate, the sample is flattened by thermoforming, pressure, or a combination thereof such that the optical properties do not substantially change in the direction normal to the surface, but the overall shape is substantially flat to be measured according to ASTM D1003 using a BYK Gardner haze meter. In another embodiment, the light transmitting cover comprises a wavelength conversion region disposed to receive blue and/or ultraviolet light and convert a percentage of incident light into light of a different wavelength such that the combination of the blue and/or UV light with the converted light output is substantially white.

### Light Output Profile of Light Emitting Device

In one embodiment, the light emitting device comprises a single linear array of light emitting diodes thermally coupled to one surface of a heat conducting member and has a light output profile with a full angular width at have maximum luminous intensity greater than one selected from the group of 20, 40, 60, 80, 100, and 120 degrees in a first light output plane orthogonal or perpendicular to the linear direction.

In another embodiment, the light emitting device is dual sided and comprises a first substantially linear array of light emitting diodes thermally coupled to a first surface on a first side of a heat conducting member and a second substantially linear array of light emitting diodes thermally coupled to a second surface on a second side of a heat conducting member. In this embodiment, the light emitting device has a first light output profile with a full angular width at have maximum luminous intensity greater than one selected from the group of 20, 40, 60, 80, 100, and 120 degrees in a first light output plane orthogonal or perpendicular to the linear direction on the first side of the heat conducting member and a second light output profile with a full angular width at have maximum luminous intensity greater than one selected from the group of 20, 40, 60, 80, 100, and 120 degrees in a second light output plane orthogonal to the linear direction on the second side of the heat conducting member. In one embodiment, the light output profile from the linear array of LEDs on a first side is substantially the same as the light output profile of the linear array of LEDs on a second side except in the opposite direction. In one embodiment, the light output profile from the linear array of LEDs on a first side of the heat conducting member mirrors the light output profile of the linear array of LEDs (substantially symmetric about the heat conducting member) on the second side of the heat conducting member opposite the first side.

### Power Source

In one embodiment, the light emitting device is powered by an electrical signal selected from the group of 12V DC, 12V AC, ˜110-120V AC, ˜220-240V AC, switchable power supply, 28V DC power supply, AC power supply, DC power supply, and 3V DC power supply. In one embodiment, the power is provided by a craft such as an automobile, aircraft, or watercraft. In another embodiment, the power supply is a battery supply, or the light emitting device has a backup battery based power supply. In another embodiment, the light emitting device comprises a solar cell and a battery such that the battery can be charged by exposure to light such as sunlight and energy is stored in the battery for future use. In one embodiment, the light emitting device is a linear LED tube for replacement of a linear fluorescent tube in a fixture and comprises an LED driver disposed within the heat conducting member or heat sink extrusion with an electrical connection to the LEDs and an electrical connection to the electrical connection pins on one or both sides of the light emitting device. In another embodiment, the light emitting device is a linear LED tube for replacement of a linear fluorescent tube in a fixture and comprises an LED driver disposed external to the heat conducting member or heat sink with an electrical connection to the LEDs and an electrical connection to the electrical connection pins on one or both sides of the light emitting device.

### Secure and Removable Connector

In one embodiment, a light emitting device comprises a aluminum extrusion heat sink, a linear array of LEDs disposed on a circuit board and thermally coupled to the aluminum extrusion heat sink, an LED driver that converts AC electrical power into DC power to drive the LEDs, electrical connection pins, and a secure and removable connector comprising a female connector, a male connector and a fastener such as, without limitation, a cable tie. In this embodiment, the leads from the electrical connection pins at one or both ends of the tube may be electrically coupled to the LED driver by the removable connector. Also, in this embodiment, the leads to circuit board comprising the LEDs may be electrically coupled to the LED driver by the removable connector means. In one embodiment, the two leads from the AC power (and the electrical connectors such as pins) are connected to a female electrical connector and the two leads connected to the LED driver are connected to a male electrical connector electrically coupled into the female connector. In this embodiment, the cable tie can be extended around the female and male connector between the two leads from the AC power and between the two leads connected to the LED driver. In this embodiment, by placing the cable tie between the leads on the male and the female connector, the cable tie will not slide off of the two connectors it is holding together. Furthermore, in this embodiment, the cable tie can securely couple the female and male connector together. In addition, by cutting the cable tie, the connectors can be easily separated such that the LED driver can be replaced, for example. In another embodiment, the light emitting device comprises a secure and removable connector means between the LED driver and the power source and the LED driver and the LEDs such that the driver may be easily replaced by cutting the fasteners and separating the connectors. In one embodiment, the fastener is a cable tie (also known as a zip tie and tie wrap). In a further embodiment, the fastener is disposed to physically couple the male and female connectors to form an electrical connection and is one selected from the group of belt hook, Rapstrap fastener, metal buckle clip, strap, snap, ring, pin, plastic cable tie, tear-away-tie, and reusable cable tie. In another embodiment, the male and female connectors are one selected from the group of: quick connect terminals, fork connectors, disconnects, fully insulated, partially insulated, locking fork, quick disconnect, and wire terminals.

### Heat Conducting Member

In one embodiment, the light emitting device comprises a heat conducting member thermally coupled to one or more arrays of light sources the heat to reduce the operating temperature of the light sources. In one embodiment, the heat conducting member is thermally coupled to one or more light emitting diodes using a thermally conductive grease, gel, epoxy, tape, adhesive, or other thermally conductive material. In one embodiment, the heat conducting member is an aluminum extrusion thermally coupled to one linear array of light emitting diodes. In one embodiment, the heat conducting member is an aluminum extrusion positioned between and thermally coupled to two linear arrays of light emitting diodes.

### Groove and Extension for Cover Seal

In one embodiment, the light emitting device comprises at least one linear groove in a heat conducting member, heat sink, or housing element; and a light transmitting cover with an extension that can slide into or snap into the groove to provide a seal. In one embodiment, an aluminum extrusion heat sink comprises linear grooves on opposite sides of the linear array of light emitting diodes and a light transmitting cover comprises extensions such that when the extensions are slid or snapped into the grooves, a water or moisture resistant seal is formed between the light transmitting cover and the heat sink. In a further embodiment, a linear gasket (such as a rubber strip) is disposed within the groove (or on the extension) such that the seal between the light transmitting cover and the heat sink has a higher water or moisture resistance. In one embodiment, the light emitting device comprises a pair of grooves on opposite sides of a heat conducting member positioned to receive the extended regions of two light transmitting covers. In this embodiment, the extensions of the first light transmitting cover and second light transmitting cover are positioned such that they extend into the first pair of grooves and second pair of grooves such that the light transmitting covers protect and seal from the environment the first linear array of LEDs and the second linear array of LEDs, all respectively. In another embodiment, the light transmitting cover further provides diffusion to improve the spatial luminance uniformity or adjust the angular light output profile.

### Groove in the Housing or Heat Sink

In one embodiment, at least one groove disposed in the housing of the light emitting device, the heat conducting member, or the extruded heat sink of the light emitting device extends substantially the length of the light emitting area of the light emitting device. In another embodiment, the groove has an opening width, G_{w}, selected from the group of: between 0.5 mm and 10 mm, between 0.5 mm and 5 mm, between 0.5 mm and 2 mm, and between 0.5 mm and 1.5 mm. In another embodiment, the groove has a uniform depth, G_{d}, selected from the group of: between 0.5 mm and 10 mm, between 0.5 mm and 5 mm, between 0.5 mm and 2 mm, and between 0.5 mm and 1.5 mm. In another embodiment, the groove has a non-uniform depth, with the depth on a first side, G_{d1}, selected from the group of: between 0.5 mm and 10 mm, between 0.5 mm and 5 mm, between 0.5 mm and 2 mm, and between 0.5 mm and 1.5 mm; and the depth on a second side, G_{d2}, selected from the group of: G_{d1}+0.5 mm, G_{d1}+1 mm, G_{d1}+1.5 mm, G_{d1}+2 mm, G_{d1}+2.5 mm, G_{d1}+3.5 mm, G_{d1}+4 mm, G_{d1}+T1 (where T1 is the average thickness of the light transmitting cover near the extension), and between G_{d1}+(0.9×T1) and G_{d1}+(1.1×T1). In another embodiment, the groove depth is non-uniform in the plane perpendicular to the linear length of the light emitting device and the light transmitting cover and heat sink form a shape with a cross-section with an outer surface substantially that of a circle. In another embodiment, the light transmitting cover and heat sink form a shape with a cross-section with an outer surface substantially that of a circle except for micro ridges in the section of the heat sink.

### Angled Side Wall of the Groove

In one embodiment, one or more grooves of the heat conducting member comprises an angled side wall with the outer portion of the side wall oriented toward the extension within the groove. In one embodiment, the angled side wall forces close contact (thus a tight seal) along one or more interfaces between the extension and the groove surface of the heat conducting member. In one embodiment, the first pair of grooves and the second pair of grooves of a dual sided light emitting device comprise a side wall with the outer portion oriented toward the first pair of extensions and second pair of extensions of the first light transmitting cover and second light transmitting cover, respectively.

### Extension in Light Transmitting Cover

In one embodiment, at least one extension in the light transmitting cover of the light emitting device has a depth, d, selected from the group of: between 0.5 mm and 10 mm, between 0.5 mm and 5 mm, between 0.5 mm and 2 mm, between 0.5 mm and 1.5 mm, greater than 0.5 mm, and less than 10 millimeters. In another embodiment, at least one extension in the light transmitting cover of the light emitting device has a height, h, selected from the group of: between 0.5 mm and 10 mm, between 0.5 mm and 5 mm, between 0.5 mm and 2 mm, between 0.5 mm and 1.5 mm, greater than 0.5 mm, and less than 10 millimeters.

### Waterproof

In one embodiment, the light source and electrical components are substantially sealed by at least one of an epoxy, resin, rubber, silicone, or polymer such that the electrical components are waterproof to a depth selected from the group of 5 feet, 10 feet, 20 feet, 30 feet, 50 feet, 100 feet, and 200 feet. In another embodiment, the light emitting device components satisfy the United Laboratories UYMR2 standards for components and fittings intended for use in electric signs and accessories. In another embodiment, the light emitting device endures a 12 hour continuous salt spray test. In another embodiment, the light emitting device endures a 24 hour continuous salt spray test. In one embodiment, the light emitting device endures a 48 hour continuous salt spray test. In one embodiment, the light emitting device endures a 60 hour salt water soak test. In one embodiment, the light emitting device endures a 120 hour salt water soak test. In another embodiment, the light emitting device endures a 240 hour salt water soak test.

In one embodiment, a light emitting device comprises a heat conducting member linear in a first linear direction with a first surface and a second surface opposite the first surface; a first linear array of light emitting diodes thermally coupled to the first surface; a second linear array of light emitting diodes thermally coupled to the second surface; a first light transmitting cover positioned to receive and transmit light from the first linear array of light emitting diodes; and a second light transmitting cover positioned to receive and transmit light from the second linear array of light emitting diodes. In another embodiment, the heat conducting member comprises a first pair of grooves positioned parallel to the first direction and on opposite sides of the first linear array of light emitting diodes, and the first light transmitting cover comprises a first pair of extensions positioned within the first pair of grooves. In another embodiment, the heat conducting member comprises a second pair of grooves positioned parallel to the first direction and on opposite sides of the second linear array of light emitting diodes, and the second light transmitting cover comprises a second pair of extensions positioned within the second pair of grooves. In a further embodiment, the first pair of grooves and the second pair of grooves comprise a side wall with the outer portion oriented toward the first pair of extensions and the second pair of extensions, respectively. In one embodiment, the first pair of grooves and the second pair of grooves form a water or moisture resistant seal with the first light transmitting cover and the second light transmitting cover, respectively. In another embodiment, the light emitting device comprises a gasket within the first pair of grooves and the second pair of grooves. In one embodiment, the first array of light emitting diodes and the second array of light emitting diodes are protected from exposure to water when the light emitting device is immersed to a depth of 5 feet. In another embodiment, the first array of light emitting diodes and the second array of light emitting diodes are protected from exposure to water when the light emitting device is immersed to a depth of 20 feet. In an embodiment, the light emitting device emits light after exposure to a 12 hour continuous salt spray test. In another embodiment, the light emitting device components satisfy the United Laboratories UYMR2 standards for components and fittings intended for use in electric signs and accessories.

In one embodiment, the light emitting diodes of the first linear array of light emitting diodes are oriented in a direction opposite the orientation light emitting diodes of the second linear array of light emitting diodes. In one embodiment, the first linear array of light emitting diodes collectively emit light more light in first emission direction substantially orthogonal to first linear direction than the second linear array of light emitting diodes; and the second linear array of light emitting diodes collectively emit light more light in second emission direction opposite the first emission direction than the first linear array of light emitting diodes. In a further embodiment, the photometric light intensity distribution profile from the first linear array of light emitting diodes is substantially similar and opposite in direction than the photometric light intensity distribution profile from the second linear array of light emitting diodes. In another embodiment, the first light transmitting cover only receives direct light from the first linear array of light emitting diodes and the second light transmitting cover only receives direct light from the second linear array of light emitting diodes. In one embodiment, the first surface contains light emitting diodes only within the first linear array and the second surface contains light emitting diodes only within the second linear array.

In one embodiment, a light emitting device comprises: a heat conducting member; a pair of linear arrays of light emitting diodes thermally coupled to opposite sides of the heat conducting member, the linear arrays of light emitting diodes oriented in substantially opposite directions; and a pair of light transmitting covers disposed to receive and transmit light from the pair of linear arrays of light emitting diodes. In another embodiment, the heat conducting member comprises linear grooves and the pair of light transmitting covers comprise extensions positioned into the grooves.

In one embodiment, a method of manufacturing a light emitting device comprises: thermally coupling a first linear array of light emitting diodes to a first surface of a heat conducting member; thermally coupling a second linear array of light emitting diodes to a second surface of the heat conducting member opposite the first surface; positioning a pair of extended regions of a first light transmitting cover into a first pair of grooves in the heat conducting member; and positioning a pair of extended regions of a second light transmitting cover into a second pair of grooves in the heat conducting member. In one embodiment, at least one of the extended regions from the first light transmitting cover and the second light transmitting cover snap into at least one of the grooves of the first pair of grooves and second pair of grooves, respectively. In another embodiment, at least one of the extended regions from the first light transmitting cover and the second light transmitting cover slide into at least one of the first pair of grooves and second pair of grooves, respectively.

The following are more detailed descriptions of various embodiments illustrated in the Figures.

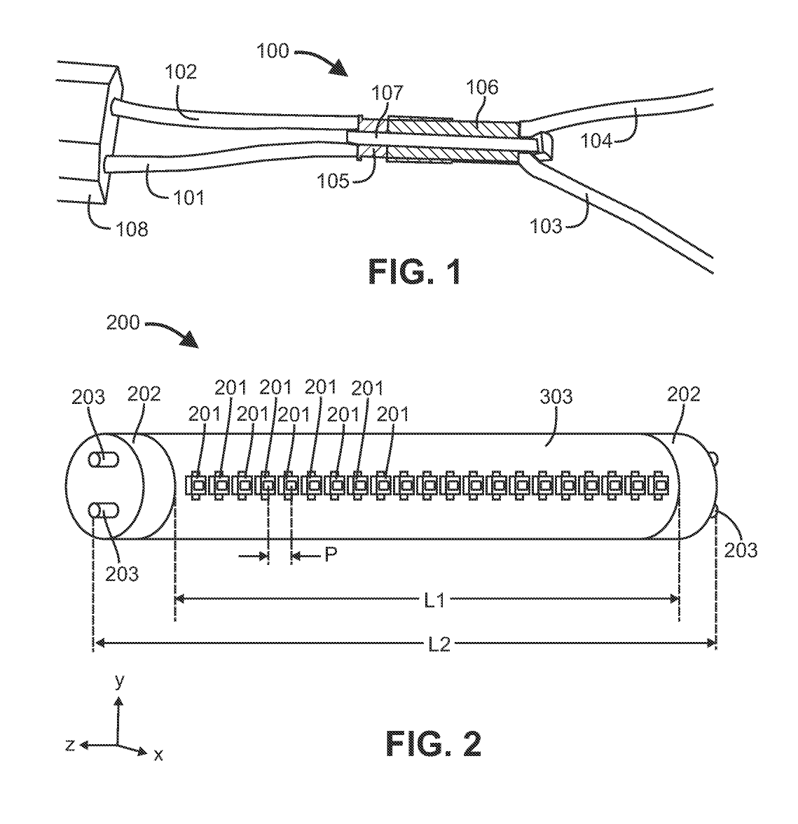

FIG. 1 is a perspective view of an embodiment of a secure and removable connector means 100 for connecting a first plurality of leads (101 and 102) to a second plurality of leads (103 and 104) using a male connector 105, a female connector 106 and a cable tie 107. The cable tie 107 is fastened between the leads 101 and 102 and between the leads 103 and 104. The leads 102 and 103 are disposed to provide AC electrical power to the LED driver 108. In this embodiment, the cable tie 107 securely holds the male connector 105 and female connector 106 together and the cable tie 107 can be cut to allow the LED driver 108 to be changed or replaced.

FIG. 2 is perspective view of an embodiment of a light emitting device 200 in the form of a LED tube linear in a first direction parallel to the z axis that can be disposed as a replacement tube in a linear fluorescent light fixture comprising a single row of LEDs 201 with a pitch, P. The linear length of the light emitting device is L2 and the linear length of the light emitting area disposed between the two end caps 202 is L1. The end caps further comprise electrical pins 203 disposed to receive electrical power for the light emitting device. A light transmitting cover 303 is disposed above the LEDs 201 to transmit the light received from the LEDs 201 out of the light emitting device 200.

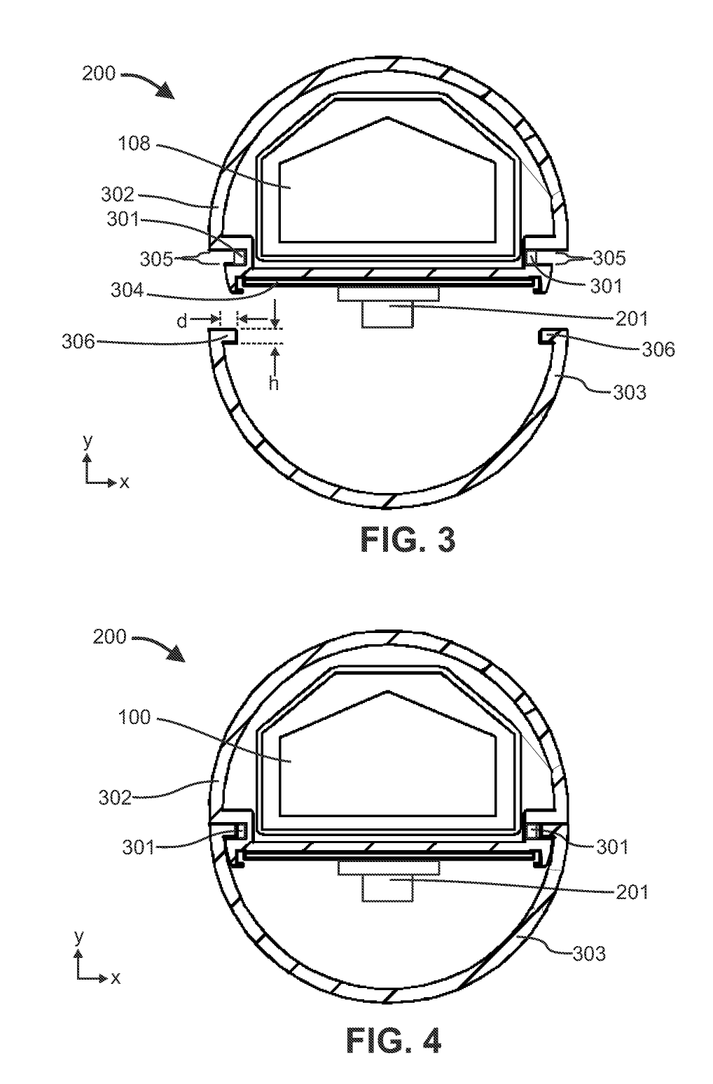

FIG. 3 is a cross-sectional view of the light emitting device 200 of FIG. 2 without the extensions 305 of the light transmitting cover 303 positioned into the grooves 305. The aluminum extrusion heat sink 302 comprises an LED driver 108 within the interior and the LEDs 201 are disposed on a circuit board 304 that is thermally coupled to the aluminum extrusion heat sink 302 by a thermally conductive adhesive (not shown). The aluminum extrusion heat sink 302 further comprises two grooves 305 disposed parallel to the linear length of the tube (parallel to the z axis) along each side. The grooves 305 are disposed to receive the extensions 306 in the light transmitting cover 303 that in this embodiment has a substantially arcuate cross section. The extensions 306 have a lateral length, d, in the x direction and a height, h, in the y direction such that the extensions 306 can be snapped or slid into place in the groove 305. In the embodiment shown in FIG. 3, the grooves 305 further comprise a gasket 301 (optional) to further reduce water penetration into the light emitting device 200 when submersed or exposed to damp conditions. In another embodiment, one or more light transmitting covers has a polygonal, arcuate or a combination thereof, cross sectional profile.

FIG. 4 is a cross sectional view of the light emitting device 200 of FIG. 3 with the light transmitting cover 303 attached such that the extensions 306 are disposed in the grooves 305. In this embodiment, the aluminum extrusion heat sink 302 and the light transmitting cover 303 provide a lateral seal to reduce or prevent water or moisture penetration into the electrical components within the light emitting device 200.

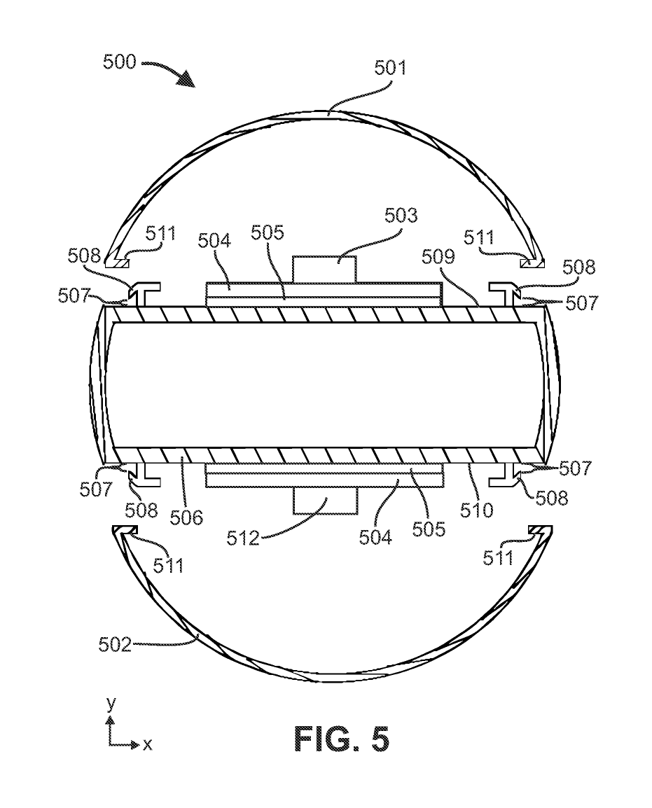

FIG. 5 is a cross sectional view of a dual sided linear light emitting device 500 before assembly of the light transmitting covers 501, 502 comprising a first linear array of LEDs 503 oriented to emit light with a directional component in the +y direction thermally coupled to a circuit board 504 that is thermally and physically coupled to a first surface 509 of a heat conducting member 506 using thermal adhesive tape 505. The light emitting device 500 is linear in a first linear direction 703 parallel to the z axis (shown in FIG. 7). The heat conducting member 506 is linear in the first linear direction 703 and comprises four linear grooves 507 with angled side walls 508 positioned to constrain the extensions 511 of the first light transmitting cover 501 and the second light transmitting cover 502. The light emitting device 500 further comprises a second linear array of LEDs 512 oriented to emit light with a directional component in the −y direction thermally coupled to a circuit board 504 that is thermally and physically coupled to a second surface 510 of the heat conducting member 506 opposite the first surface 509 using thermal adhesive tape 505.

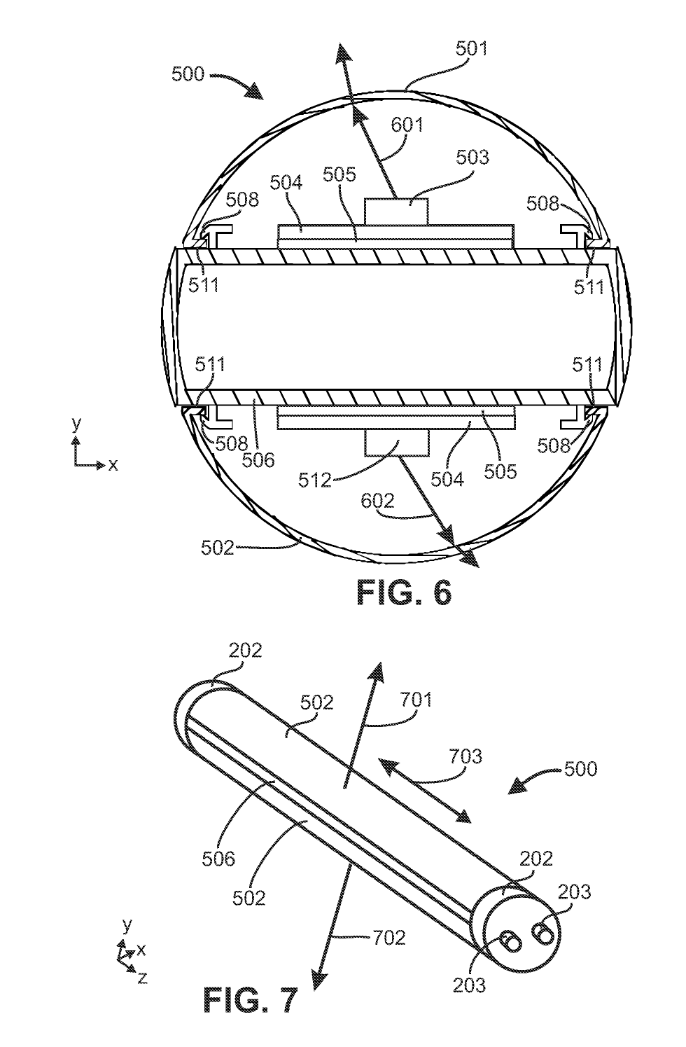

FIG. 6 is a cross sectional view of the dual sided linear light emitting device 500 of FIG. 5 with the extensions 508 of the first light transmitting cover 501 positioned within the linear grooves 507 where the extensions 511 form a seal with the angled side walls 508. The first light transmitting cover 501 is positioned to receive and transmit light 601 from the first linear array of LEDs 503. The second light transmitting cover 502 is positioned to receive and transmit light 602 from the second linear array of LEDs 512.

FIG. 7 is a perspective view of the light emitting device 500 of FIG. 5. The light emitting device 500 is linear in the first linear direction 703 parallel to the z axis. The light emitting device 500 comprises two end caps 202, each with electrical pins 203 positioned to receive electrical power. The first linear array of LEDs 503 emit more light in the first emission direction 701 (parallel to the +y direction) orthogonal to the first linear direction 703 than the second linear array of LEDs 512. The second linear array of LEDs 512 emit more light in the second emission direction 702 (parallel to the −y direction) orthogonal to the first linear direction 703 and opposite the first emission direction 701 than the first linear array of LEDs 503. In one embodiment, the light emitting device 500 further comprises gaskets in the grooves 507 to seal the linear array of LEDs 503, 512 from the environment external to the light emitting device 500.

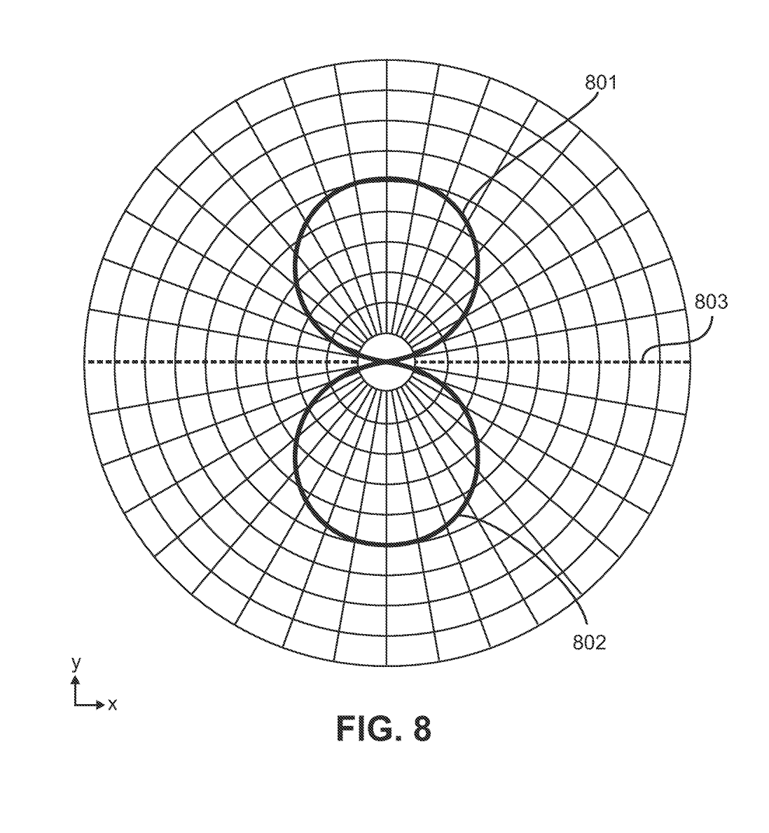

FIG. 8 is a polar plot of the luminous intensity distribution profile in the x-y plane of the light from the dual sided light emitting device 500 of FIG. 7. The profile is substantially symmetric about the heat conducting member 506 in a direction parallel to the x axis and comprises a first light intensity profile distribution 801 from the first linear array of LEDs 503 and a second light intensity profile distribution 802 from the second linear array of LEDs 512. As shown in FIG. 8, the light output profile 801 from the first linear array of LEDs 503 is substantially similar and opposite in direction than the light output profile 802 from the second linear array of LEDs 512.

### EQUIVALENTS

Those skilled in the art will recognize, or be able to ascertain using no more than routine experimentation, numerous equivalents to the specific procedures described herein. Such equivalents are considered to be within the scope of the invention. Various substitutions, alterations, and modifications may be made to the invention without departing from the spirit and scope of the invention. Other aspects, advantages, and modifications are within the scope of the invention. The contents of all references, issued patents, and published patent applications cited throughout this application are hereby incorporated by reference. The appropriate components, processes, and methods of those patents, applications and other documents may be selected for the invention and embodiments thereof. This application is intended to cover any adaptations or variations of the specific embodiments discussed herein. Therefore, it is intended that this disclosure be limited only by the claims and the equivalents thereof.

Unless otherwise indicated, all numbers expressing feature sizes, amounts, and physical properties used in the specification and claims are to be understood as being modified by the term “about”. Accordingly, unless indicated to the contrary, the numerical parameters set forth in the foregoing specification and attached claims are approximations that can vary depending upon the desired properties sought to be obtained by those skilled in the art utilizing the teachings disclosed herein. Unless indicated to the contrary, all tests and properties are measured at an ambient temperature of 25 degrees Celsius or the environmental temperature within or near the device when powered on (when indicated) under constant ambient room temperature of 25 degrees Celsius.

What is claimed is:

1. A light emitting device comprising:
a. a heat conducting member linear in a first linear direction with a first surface and a second surface opposite the first surface;
b. a first linear array of light emitting diodes thermally coupled to the first surface;
c. a second linear array of light emitting diodes thermally coupled to the second surface;
d. a first light transmitting cover positioned to receive and transmit light from the first linear array of light emitting diodes; and
e. a second light transmitting cover positioned to receive and transmit light from the second linear array of light emitting diodes.

2. The light emitting device of claim 1 wherein the heat conducting member comprises a first pair of grooves positioned parallel to the first direction and on opposite sides of the first linear array of light emitting diodes, and the first light transmitting cover comprises a first pair of extensions positioned within the first pair of grooves.

3. The light emitting device of claim 2 wherein the heat conducting member comprises a second pair of grooves positioned parallel to the first direction and on opposite sides of the second linear array of light emitting diodes, and the second light transmitting cover comprises a second pair of extensions positioned within the second pair of grooves.

4. The light emitting device of claim 3 wherein the first pair of grooves and the second pair of grooves comprise a side wall with the outer portion oriented toward the first pair of extensions and the second pair of extensions, respectively.

5. The light emitting device of claim 3 wherein the first pair of grooves and the second pair of grooves form a water or moisture resistant seal with the first light transmitting cover and the second light transmitting cover, respectively.

6. The light emitting device of claim 3 further comprising a gasket positioned within the first pair of grooves and the second pair of grooves.

7. The light emitting device of claim 3 wherein the first array of light emitting diodes and the second array of light emitting diodes are protected from exposure to water when the light emitting device is immersed to a depth of 5 feet.

8. The light emitting device of claim 3 wherein the first array of light emitting diodes and the second array of light emitting diodes are protected from exposure to water when the light emitting device is immersed to a depth of 20 feet.

9. The light emitting device of claim 3 wherein the light emitting device emits light after exposure to a 12 hour continuous salt spray test.

10. The light emitting device of claim 3 wherein the light emitting device components satisfy the United Laboratories UYMR2 standards for components and fittings intended for use in electric signs and accessories.

11. The light emitting device of claim 1 wherein the light emitting diodes of the first linear array of light emitting diodes are oriented in a direction opposite the orientation of the diodes of the second linear array of light emitting diodes.

12. The light emitting device of claim 1 wherein the first linear array of light emitting diodes collectively emit light more light in first emission direction substantially orthogonal to first linear direction than the second linear array of light emitting diodes; and the second linear array of light emitting diodes collectively emit light more light in second emission direction opposite the first emission direction than the first linear array of light emitting diodes.

13. The light emitting device of claim 1 wherein the photometric light intensity distribution profile from the first linear array of light emitting diodes is substantially similar and opposite in direction than the photometric light intensity distribution profile from the second linear array of light emitting diodes.

14. The light emitting device of claim 1 wherein the first light transmitting cover only receives direct light from the first linear array of light emitting diodes and the second light transmitting cover only receives direct light from the second linear array of light emitting diodes.

15. The light emitting device of claim 1 wherein the first surface contains light emitting diodes only within the first linear array and the second surface contains light emitting diodes only within the second linear array.

16. A light emitting device comprising:
a. a heat conducting member;
b. a pair of linear arrays of light emitting diodes thermally coupled to opposite sides of the heat conducting member, the linear arrays of light emitting diodes oriented in substantially opposite directions; and
c. a pair of light transmitting covers disposed to receive and transmit light from the pair of linear arrays of light emitting diodes.

17. The light emitting device of claim 16 wherein the heat conducting member comprises linear grooves and the pair of light transmitting covers comprise extensions positioned into the grooves.

18. A method of manufacturing a light emitting device, said method comprising:
thermally coupling a first linear array of light emitting diodes to a first surface of a heat conducting member;
thermally coupling a second linear array of light emitting diodes to a second surface of the heat conducting member opposite the first surface;
positioning a pair of extended regions of a first light transmitting cover into a first pair of grooves in the heat conducting member; and
positioning a pair of extended regions of a second light transmitting cover into a second pair of grooves in the heat conducting member.

19. The method of claim 18 wherein at least one of the extended regions from the first light transmitting cover and the second light transmitting cover snap into at least one of the grooves of the first pair of grooves and second pair of grooves, respectively.

20. The method of claim 18 wherein at least one of the extended regions from the first light transmitting cover and the second light transmitting cover slide into at least one of the first pair of grooves and second pair of grooves, respectively.
